(19) United States
(12) Patent Application Publication
(10) Pub. No.: US 2011/0073179 A1
(43) Pub. Date: Mar. 31, 2011

(54) ILLUMINANT TYPE TRANSPARENT SOLAR CELL DEVICE

(76) Inventors: Hsin-Chun LU, Kwei-Shan (TW); Chun-Lung Chu, Kwei-Shan (TW); Chen-Sung Chang, Kwei-Shan (TW); Jo-Ling Lu, Kwei-Shan (TW); Chen-Yang Lo, Kwei-Shan (TW)

(21) Appl. No.: 12/890,148

(22) Filed: Sep. 24, 2010

(30) Foreign Application Priority Data
Sep. 25, 2009 (TW) 098132464

(51) Int. Cl. H01L 31/00

(52) U.S. Cl. 136/256

(57) ABSTRACT

An illuminant transparent solar cell device, comprising a transparent substrate and the following layers disposed from bottom up sequentially on the transparent substrate: a transparent fluorescent layer, a p-type transparent conductive oxide layer, an intrinsic-type transparent conductive oxide layer, a n-type transparent conductive oxide layer, and an anti-reflection layer serving as a protection layer. In the illuminant transparent solar cell device, the characteristics of a p-type and an n-type transparent conductive oxide layers as well as a transparent fluorescent layer are utilized so that sunlight can not only be used to provide natural lighting in daytime but also be used to generate electricity which is stored in an electricity storage device by transmitting through this device while the electricity stored therein can be used to provide indoor lighting at night, thus saving the consumption of fossil fuel energy.

### BACKGROUND OF THE INVENTION

1. Field of the Invention

The present invention relates to an photovoltaic energy conversion device, and in particular to an illuminant transparent solar cell device.

2. The Prior Arts

Caused by the rapid economic growth and the improvement of living quality, the worldwide consumption of fossil fuel energy for generating electricity utilized in illumination is steadily increasing. Therefore, it is an important and urgent task to find alternative energy sources and to reduce the consumption of electricity used in illumination. Among the numerous alternative energy sources available, solar cells have promising potentials to become the mainstream of energy sources in the near foreseeable future, due to its various advantages such as cleanness, abundant supply, and high accessibility. This situation is particularly true when the global community is under the pressures of the uprising oil price and the global warming problems.

Among the various solar cells currently employed, non-transparent materials are used in the majority of them to increase their cell efficiency at the expense of low visible light transmission, limiting the installation of these solar cell to the locations that do not need to consider lighting and hindering the widespread utilization of these solar cells. For instance, if conventional silicon solar cells are installed on all the windows of a building, natural sunlight is not able to penetrate through these solar cells to provide natural lighting to the building because sunlight is totally absorbed by these silicon solar cells and is not able to transmit through them. To resolve this issue, transparent solar cells have been proposed and developed by researchers to be installed on the windows of the buildings to allow sunlight to transmit through these transparent solar cells to provide the buildings with natural lighting while generating electricity. Although these transparent solar cells can provide natural lighting by allowing the sunlight to transmit through them during the daytime, they are not able to be utilized as lighting source to provide lighting during the nighttime.

In view of the problems and shortcomings of the prior art, the present invention provides an illuminant transparent solar cell device, so as to overcome the problems of the prior arts.

### SUMMARY OF THE INVENTION

The major objective of the present invention is to provide an illuminant transparent solar cell device to provide natural lighting and electricity at daytime through sunlight and to provide lighting at nighttime. This illuminant transparent solar cell utilizes the characteristics of a p-type and a n-type transparent conductive oxide layers as well as a transparent fluorescent layer. With this illuminant transparent solar cell device, sunlight can not only be used to provide natural lighting in daytime but also be used to generate electricity which is stored in an electricity storage device by transmitting through this device. The electricity stored therein can be used to provide indoor lighting at night, thus saving the consumption of fossil fuel energy.

To achieve the above-mentioned objective, the present invention provides an illuminant transparent solar cell device, comprising a transparent substrate and the following layers disposed from bottom up sequentially on the transparent substrate: a transparent fluorescent layer, a p-type transparent conductive oxide layer, an intrinsic-type transparent conductive oxide layer, an n-type transparent conductive oxide layer, and an anti-reflection layer serving as a protection layer.

Further scope of the applicability of the present invention will become apparent from the detailed description given hereinafter. However, it should be understood that the detailed description and specific examples, while indicating preferred embodiments of the present invention, are given by way of illustration only, since various changes and modifications within the spirit and scope of the present invention will become apparent to those skilled in the art from this detailed description.

### BRIEF DESCRIPTION OF THE DRAWINGS

The related drawings in connection with the detailed description of the present invention to be made later are described briefly as follows, in which:

FIG. 1 is a schematic diagram of an illuminant transparent solar cell device according to the present invention;

FIG. 2 is a schematic diagram of an illuminant transparent solar cell device operated in daytime according to the present invention; and

FIG. 3 is a schematic diagram of an illuminant transparent solar cell device operated at night according to the present invention.

### DETAILED DESCRIPTION OF THE PREFERRED EMBODIMENT

The purpose, construction, features, functions and advantages of the present invention can be appreciated and understood more thoroughly through the following detailed description with reference to the attached drawings.

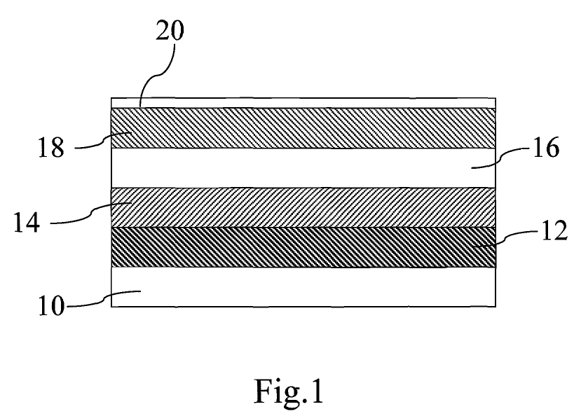

In the present invention, an illuminant transparent solar cell device is provided, such that it is not only capable of converting light into electricity, but it is also capable of converting electricity back into light through the built-in light emitting diode. Refer to FIG. 1 for a schematic diagram of an illuminant transparent solar cell device according to the present invention. As shown in FIG. 1, an illuminant transparent solar cell device comprises a transparent substrate 10, which can be chosen from glass, quartz, transparent plastic, mono-crystal Al₂O₃, or flexible transparent material, and the following layers disposed sequentially from the bottom up on the transparent substrate 10: a transparent fluorescent layer 12, a p-type transparent conductive oxide layer 14 used as a first type transparent conductive oxide layer, an intrinsic-type transparent conductive oxide layer 16, a n-type transparent conductive oxide layer 18 used as a second type transparent conductive oxide layer, and an anti-reflection layer 20 serving as a protection layer. The lamination sequence of the various layers mentioned above is conducted through taking into consideration of the energy gaps of the layers. In addition, for the selection of materials for the layers, the transparent fluorescent layer 12 can be Ce³⁺ doped LaPO₄ or Mn⁺² doped Zn₂SiO₄; the p-type transparent conductive oxide layer 14 can be chosen from Cu₂O, ZnO, N doped ZnO, N doped ZnO-Al, NiO, FeO, CuAlO₂, CuGaO₂, CuScO₂, CuCrO₂, CuInO₂, CuY O₂, AgInO₂, or SrCuO₂; the n-type transparent conductive oxide layer 18 can be chosen from In₂O₃, SnO₂, ZnO, CdO, ITO, IZO, AZO, or GZO. Furthermore, the anti-reflection layer 20 should also be transparent oxide material. From the description mentioned above, it can be realized that, the various layers of an illuminant transparent solar cell device are made of transparent oxide materials, such that they are capable of providing better illumination than the conventional solar cells or light-emitting-diodes.

Moreover, the relative positions of the p-type transparent conductive oxide layer 14 and the n-type transparent conductive oxide layer 18 can be exchanged, or the anti-reflection layer 20 can be omitted, or the intrinsic-type transparent conductive oxide layer 16 can be omitted, so that the n-type transparent conductive oxide layer 18 can be disposed directly on the p-type transparent conductive oxide layer 14 such that the solar cell thus produced is still capable of performing the conversion of light energy into electrical energy and vice versa.

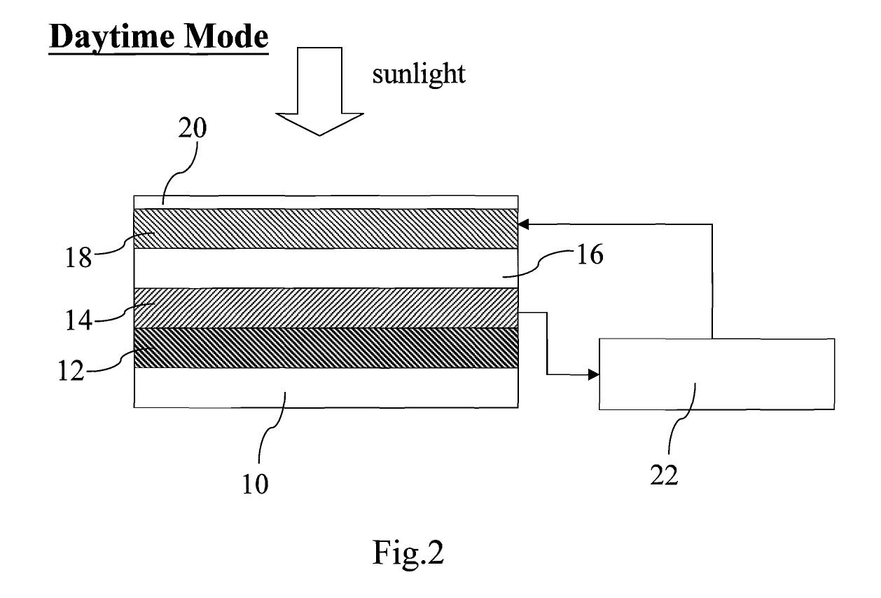

Subsequently, refer to FIG. 2 for a schematic diagram of an illuminant transparent solar cell device operated in daytime according to the present invention. When operated in daytime, the solar cell device of the present invention will function like a transparent solar cell. As such, when sunlight is irradiated upon the transparent conductive oxide layers 14, 16, and 18, the ultraviolet light portion will be absorbed by the transparent conductive oxide layers 14 and 18, thus they are induced to produce electrons and holes respectively. Since the transparent conductive oxide layers 14 and 18 are intrinsically provided with positive and negative charges, these positive and negative charges will create a built-in electrical field and this built-in electrical field will make the electrons and holes produced by the sunlight irradiation to flow in the solar cell device. Therefore, an electrical current is made to flow from p-type transparent conductive oxide layer 14 to an energy storage device 22 to store the electricity generated from the irradiated sunlight. In addition, since the energy of visible lights in sunlight is lower than the band gaps of the materials of the related layers, visible light will penetrate through the illuminant transparent solar cell device, hereby achieving natural lighting effect.

In case that, in the structure mentioned above, the relative positions of the p-type and n-type transparent conductive oxide layers 14 and 18 are exchanged with other, or the anti-reflection layer 20 is omitted, or the intrinsic-type transparent conductive oxide layer 16 is omitted, then the daytime operation mode is the same as that mentioned above, and it is still capable of performing the conversion of light into electricity and vice versa.

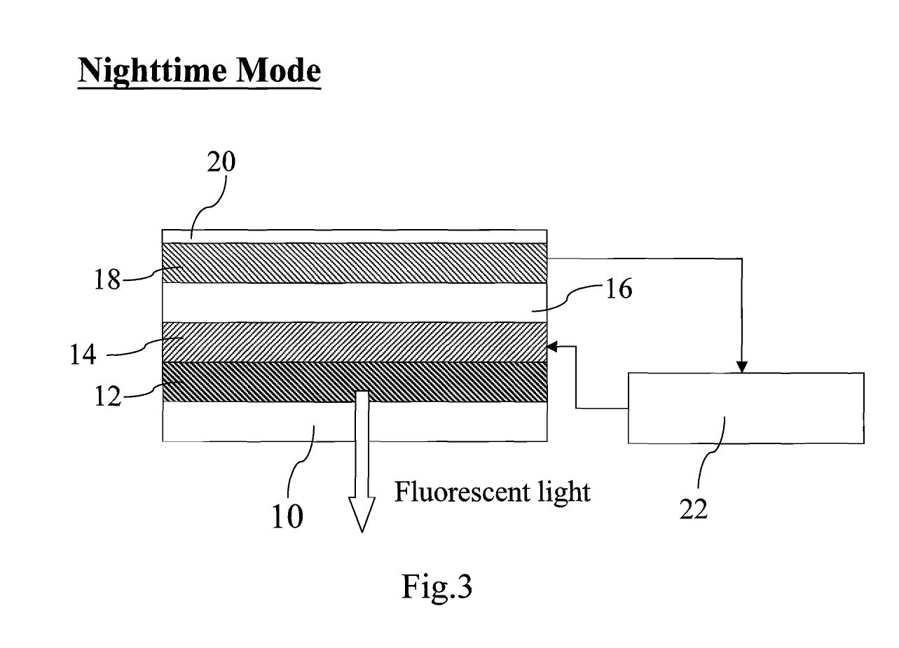

Finally, refer to FIG. 3 for a schematic diagram of an illuminant transparent solar cell device operated at night according to the present invention. As shown in FIG. 3, in nighttime, its operation mode is the same as that of an LED. When a current flows from the energy storage device 22 toward the p-type transparent conductive oxide layer 14 and into the solar cell device, the electrons and holes will flow from the electrodes to the p-type and n-type transparent conductive oxide layers 14 and 18 under the influences of electric field. Wherein, the intrinsic-type transparent conductive oxide layer 16 is used to prolong the life cycles of the carriers. When the electrons and holes recombine, photons will be released. Due to the existence of the anti-reflection layer 20, lights will be concentrated and emitted downward, and the wavelength of the emitted lights is dependent on the band gaps of the p-type and n-type transparent conductive oxide layers 14 and 18. However, when the electrons and holes recombine, the photons released are usually invisible, and these invisible photons can stimulate the fluorescent material in the transparent fluorescent layer 12 to emit visible lights, so as to realize the illumination effect at night.

In case that, in the structure mentioned above, the relative positions of the p-type and n-type transparent conductive oxide layers 14 and 18 are exchanged with each other, or the anti-reflection layer 20 is omitted, or the intrinsic-type transparent conductive oxide layer 16 is omitted, then the nighttime operation mode is the same as that mentioned above, and it is still capable of converting electrical energy into light energy, and that will stimulate the fluorescent material in the transparent fluorescent layer 12 into emitting visible lights, so as to realize the illumination effect at night.

Therefore, through the application of the present invention, solar energy can be saved and stored in the form of electricity in daytime, and it can be converted back into light at night for illumination, so as to save consumption of the fossil fuel energy. Moreover, in actual application, the solar cell of the present invention can be installed at the location originally requiring glass pane or transparent partitions, and it can also be installed in a building structure for putting the building, solar cells, and light-emitting-diodes integrally together. As such, it can be installed directly on or even replace the window glass pane of an ordinary household, the glass curtain of a mansion, or the window glass pane of a vehicle. Furthermore, its mounting and demounting is simple and easy without having to change the structure of the original building or the design of the vehicle, thus it will not cause the increase of payload, hereby increasing the practicality and convenience of using solar cell as an effective energy source.

Summing up the above, the present invention utilize the characteristics of a p-type and an n-type transparent conductive oxide layers as well as a transparent fluorescent layer so that sunlight can not only be used to provide natural lighting in daytime but also be used to generate electricity which is stored in an electricity storage device by transmitting through this device while the electricity stored therein can be used to provide indoor lighting at night, thus saving the consumption of fossil fuel energy.

The above detailed description of the preferred embodiment is intended to describe more clearly the characteristics and spirit of the present invention. However, the preferred embodiments disclosed above are not intended to be any restrictions to the scope of the present invention. Conversely, its purpose is to include the various changes and equivalent arrangements which are within the scope of the appended claims.

What is claimed is:

1. An illuminant transparent solar cell device, comprising:
a transparent substrate;
a fluorescent layer, disposed on said transparent substrate;
a first type transparent conductive oxide layer, disposed on said fluorescent layer; and
a second type transparent conductive oxide layer, disposed on said first type transparent conductive oxide layer.

2. The illuminant transparent solar cell device as claimed in claim 1, further comprising:
an intrinsic-type transparent conductive oxide layer disposed between said first type transparent conductive oxide layer and said second type transparent conductive oxide layer.

3. The illuminant transparent solar cell device as claimed in claim 1, further comprising:
an anti-reflection layer, disposed on said second type transparent conductive oxide layer.

4. The illuminant transparent solar cell device as claimed in claim 3, wherein
said anti-reflection layer comprises transparent material.

5. The illuminant transparent solar cell device as claimed in claim 1, wherein
said first and second type transparent conductive oxide layers are a n-type transparent conductive oxide layer and a p-type transparent conductive oxide layer respectively.

6. The illuminant transparent solar cell device as claimed in claim 1, further comprising:
said first and second type transparent conductive oxide layers are said p-type transparent conductive oxide layer and said n-type transparent conductive oxide layer respectively.

7. The illuminant transparent solar cell device as claimed in claim 6, wherein
said p-type transparent conductive oxide layer comprises Cu₂O, ZnO, N doped ZnO, N doped ZnO-Al, NiO, FeO, CuAlO₂, CuGaO₂, CuScO₂, CuCrO₂, CuInO₂, CuY O₂, AgInO₂, or SrCuO₂.

8. The illuminant transparent solar cell device as claimed in claim 6, wherein
said n-type transparent conductive oxide layer comprises In₂O₃, SnO₂, ZnO, CdO, ITO, IZO, AZO, or GZO.

9. The illuminant transparent solar cell device as claimed in claim 1, wherein
said transparent substrate comprises glass, quartz, transparent plastic, mono-crystal Al₂O₃, or flexible transparent materials.

10. The illuminant transparent solar cell device as claimed in claim 1, wherein
said fluorescent layer is a transparent fluorescent layer.

11. The illuminant transparent solar cell device as claimed in claim 1, wherein
said fluorescent layer comprises Ce⁺³ doped LaPO₄ or Mn⁺² doped Zn₂SiO₄.

12. The illuminant transparent solar cell device as claimed in claim 1, wherein
said first and second transparent conductive oxide layers are capable of absorbing light and converting it into electricity, and then storing it into an energy storage device.

13. The illuminant transparent solar cell device as claimed in claim 12, wherein
said first and second transparent conductive oxide layers are capable of receiving said electricity from said energy storage device, converting it into invisible light, and using it to stimulate fluorescent material of said fluorescent layer to emit light.

14. The illuminant transparent solar cell device as claimed in claim 5, wherein said p-type transparent conductive oxide layer comprises Cu₂O, ZnO, N doped ZnO, N doped ZnO-Al, NiO, FeO, CuAlO₂, CuGaO₂, CuScO₂, CuCrO₂, CuInO₂, CuY O₂, AgInO₂, or SrCuO₂.

15. The illuminant transparent solar cell device as claimed in claim 5, wherein said n-type transparent conductive oxide layer comprises In₂O₃, SnO₂, ZnO, CdO, ITO, IZO, AZO, or GZO.
